(19) United States
(12) Patent Application Publication
(10) Pub. No.: US 2020/0066682 A1
(43) Pub. Date: Feb. 27, 2020

(54) SEMICONDUCTOR PACKAGE AND METHOD OF MANUFACTURING THE SAME

(71) Applicant: Samsung Electronics Co., Ltd., Suwon-si (KR)

(72) Inventors: Taeseong KIM, Suwon-si (KR); Kwangjin MOON, Hwaseong-si (KR); Hyoju KIM, Seoul (KR); Junhong MIN, Seoul (KR); Hakseung LEE, Seoul (KR)

(73) Assignee: Samsung Electronics Co., Ltd., Suwon-si (KR)

(21) Appl. No.: 16/408,891

(22) Filed: May 10, 2019

(30) Foreign Application Priority Data
Aug. 22, 2018 (KR) 10-2018-0098076

(51) Int. Cl. H01L 25/065; H01L 23/00; H01L 25/00; H01L 21/768

(52) U.S. Cl. CPC H01L 25/0657; H01L 2224/80001; H01L 24/05; H01L 24/48; H01L 24/73; H01L 24/83; H01L 24/85; H01L 24/92; H01L 25/50; H01L 24/08; H01L 21/76898; H01L 24/03; H01L 24/27; H01L 24/94; H01L 2224/32225; H01L 2225/06541; H01L 2224/08146; H01L 2224/0557; H01L 2225/06562; H01L 2224/04042; H01L 2225/0651; H01L 2224/73215; H01L 2224/92247; H01L 2224/32145; H01L 2224/33181; H01L 24/33; H01L 2225/06506; H01L 2224/73265; H01L 2224/48091; H01L 2224/48106; H01L 2224/48145; H01L 2224/48227; H01L 24/32

(57) ABSTRACT

Disclosed are semiconductor packages and methods of manufacturing the same. The semiconductor package comprises a substrate, a first unit structure attached to the substrate, and a second unit structure attached to the first unit structure. Each of the first and second unit structures comprises an adhesive layer, a lower semiconductor chip on the adhesive layer, an upper semiconductor chip on and in contact with the lower semiconductor chip, and a plurality of vias penetrating the upper semiconductor chip and connecting with the lower and upper semiconductor chips.

### CROSS-REFERENCE TO RELATED APPLICATION

This U.S. nonprovisional application claims priority under 35 U.S.0 § 119 to Korean Patent Application No. 10-2018-0098076 filed on Aug. 22, 2018 in the Korean Intellectual Property Office, the entire contents of which are hereby incorporated by reference.

### BACKGROUND

The present inventive concepts relate to a semiconductor package and a method of manufacturing the same, and more particularly, to a semiconductor package including a stacked integrated circuit and a method of manufacturing the same.

A typical stacked package has a structure in which a number of substrates are stacked. For example, the stacked package includes semiconductor chips that are sequentially stacked on a printed circuit board (PCB). Connection pads are formed on the semiconductor chips. Bonding wires are used to couple the connection pads such that the semiconductor chips are electrically connected to each other. The printed circuit board is provided thereon with a logic chip that controls the semiconductor chips.

Portable devices have been increasingly in demand in recent electronic product markets, and as a result, it is desirable for reduction in size and/or weight of electronic parts in the portable devices. To accomplish the reduction in size and/or weight of the electronic parts, reduction in size of mounting parts, and/or integration of individual devices into a single package are implemented. In particular, semiconductor packages operated with high frequency signals may require compactness and/or improved electrical characteristics.

### SUMMARY

Some example embodiments of the present inventive concepts provide a compact-sized semiconductor package and a method of manufacturing the same.

Some example embodiments of the present inventive concepts provide a semiconductor package with improved electrical characteristics and a method of manufacturing the same.

An object of the present inventive concepts is not limited to the mentioned above, and other objects which have not been mentioned above will be clearly understood to those skilled in the art from the following description.

According to some example embodiments of the present inventive concepts, a semiconductor package may comprise: a substrate; a first unit structure attached to the substrate; and a second unit structure attached to the first unit structure. Each of the first and second unit structures may comprise: an adhesive layer; a lower semiconductor chip on the adhesive layer; an upper semiconductor chip on and in contact with the lower semiconductor chip; and a plurality of vias penetrating the upper semiconductor chip and connecting with the lower and upper semiconductor chips.

According to some example embodiments of the present inventive concepts, a method of manufacturing a semiconductor package may comprise: forming a unit structure; attaching the unit structure to a substrate; and connecting the unit structure to the substrate with a bonding wire. Forming the unit structure may comprise: providing a lower semiconductor chip having on a front side thereof a lower chip pad and a lower insulating layer; providing an upper semiconductor chip having on a front side thereof an upper chip pad and an upper insulating layer; providing the upper semiconductor chip on the lower semiconductor chip such that the upper insulating layer and the lower insulating layer are in contact with each other; forming vias that penetrate the upper semiconductor chip; forming a structure pad on a rear side of the upper semiconductor chip; and forming an adhesive layer on a rear side of the lower semiconductor chip.

### BRIEF DESCRIPTION OF THE DRAWINGS

FIG. 1 illustrates a cross-sectional view showing a semiconductor package according to some example embodiments of the present inventive concepts.

FIG. 2 illustrates a cross-sectional view showing a semiconductor package according to some example embodiments of the present inventive concepts.

FIGS. 3 to 10 illustrate cross-sectional views showing a method of manufacturing a semiconductor package according to some example embodiments of the present inventive concepts.

FIGS. 11 to 14 illustrate cross-sectional views showing a method of manufacturing a semiconductor package according to some example embodiments of the present inventive concepts.

### DETAILED DESCRIPTION OF EMBODIMENTS

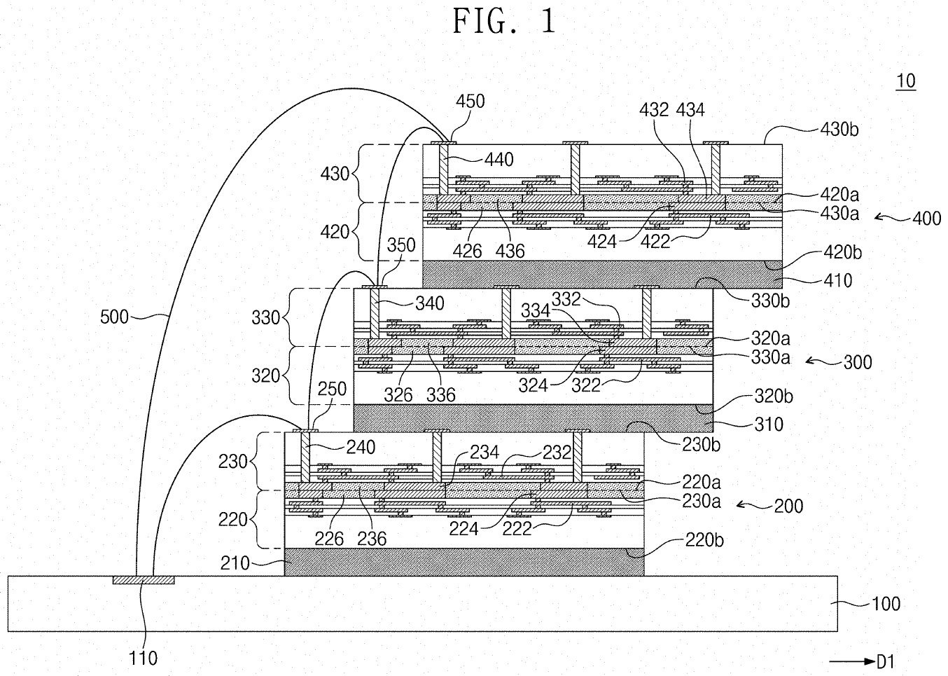

The following will now describe semiconductor packages according to the present inventive concepts with reference to the accompanying drawings. FIG. 1 illustrates a cross-sectional view showing a semiconductor package according to some example embodiments of the present inventive concepts.

Referring to FIG. 1, a semiconductor package 10 may include a substrate 100 and unit structures 200, 300, and/or 400.

The substrate 100 may be a printed circuit board (PCB) having a signal pattern on a top surface thereof. The substrate 100 may be provided on its top surface with substrate pads 110. The substrate 100 may be provided on its bottom surface with external terminals (not shown). The external terminals may include metal, such as tin (Sn), lead (Pb), nickel (Ni), gold (Au), silver (Ag), copper (Cu), bismuth (Bi), or a combination thereof. The external terminals may include a solder ball or a solder pad, and based on type of the external terminals, the semiconductor package 10 may have one of a ball grid array (B GA) type, a fine ball-grid array (FBGA) type, or a land grid array (LGA).

The unit structures 200, 300, and/or 400 may be provided on the substrate 100. The unit structures 200, 300, and/or 400 may include a first unit structure 200 attached to the substrate 100, a second unit structure 300 stacked on the first unit structure 200, and a third unit structure 400 stacked on the second unit structure 300. FIG. 1 shows the semiconductor package 10 with three unit structures 200, 300, and/or 400, but the number of unit structures may be less or more than three. The unit structures 200, 300, and/or 400 may be disposed to constitute an offset stack structure, and may be connected to each other through bonding wires 500. For example, the unit structures 200, 300, and/or 400 may be stacked in a stepwise fashion along a first direction D1 parallel to the top surface of the substrate 100, and thus may form an ascending staircase shape. Because the unit structures 200, 300, and/or 400 are stacked in a stepwise fashion, each of the unit structures 200, 300, and/or 400 may have a top surface that is partially exposed.

The following will representatively explain the first unit structure 200, and the second and third unit structures 300 and 400 will be described in comparison with the first unit structure 200. The first unit structure 200 will be discussed with reference to FIG. 1, and the description of the first unit structure 200 may be identically or similarly applicable to the second and third unit structures 300 and 400.

The first unit structure 200 may include a first lower semiconductor chip 220, a first upper semiconductor chip 230, and/or a first adhesive layer 210.

The first lower semiconductor chip 220 may be a memory chip, such as DRAM, SRAM, MRAM, or Flash memory. The first lower semiconductor chip 220 may include a silicon material. The first lower semiconductor chip 220 may have a front side 220a and a rear side 220b. In this description, the term “front side” may mean one surface on which are formed pads of a semiconductor chip, which one surface corresponds to an active surface of an integrated device in a semiconductor chip, and the term “rear side” may mean other surface opposite to the front side. The first lower semiconductor chip 220 may include, on the front side 220a thereof, first lower conductive patterns 222 and first lower chip pads 224. The first lower chip pads 224 may be electrically connected through the first lower conductive patterns 222 to an integrated device or integrated circuits in the first lower semiconductor chip 220. The front side 220a of the first lower semiconductor chip 220 may be provided thereon with a first lower insulating layer 226 covering the first lower conductive patterns 222. The first lower insulating layer 226 may expose the first lower chip pads 224. The first lower chip pads 224 may have their top surfaces coplanar with that of the first lower insulating layer 226. The first lower insulating layer 226 may include oxide. For example, the first lower insulating layer 226 may include silicon oxide (SiOx).

The first upper semiconductor chip 230 may be provided on the first lower semiconductor chip 220. The first upper semiconductor chip 230 may be of the same type as the first lower semiconductor chip 220. For example, the first upper semiconductor chip 230 may be a memory chip. The first upper semiconductor chip 230 may include a silicon material. The first upper semiconductor chip 230 may have a front side 230a and a rear side 230b. The first upper semiconductor chip 230 may include, on the front side 230a thereof, first upper conductive patterns 232 and first upper chip pads 234. When viewed in plan, an arrangement of the first upper chip pads 234 may correspond to that of the first lower chip pads 224. The first upper chip pads 234 may be electrically connected through the first upper conductive patterns 232 to an integrated device or integrated circuits in the first upper semiconductor chip 230. The front side 230a of the first upper semiconductor chip 230 may be provided thereon with a first upper insulating layer 236 covering the first upper conductive patterns 232. The first upper insulating layer 236 may expose the first upper chip pads 234. The first upper chip pads 234 may have their bottom surfaces coplanar with that of the first upper insulating layer 236. The first upper insulating layer 236 may include the same material as that of the first lower insulating layer 226. The first upper insulating layer 236 may include oxide. For example, the first upper insulating layer 236 may include silicon oxide (SiOx).

The front side 220a of the first lower semiconductor chip 220 may be in contact with the front side 230a of the first upper semiconductor chip 230. For example, the first lower chip pads 224 may be in contact with the first upper chip pads 234. The first lower semiconductor chip 220 and the first upper semiconductor chip 230 may be electrically connected to each other through the first lower chip pads 224 and the first upper chip pads 234. The first lower insulating layer 226 may be in contact with the first upper insulating layer 236. In example embodiments, the first lower insulating layer 226 and the first upper insulating layer 236 may have a continuous configuration and an invisible interface therebetween. For example, the first lower insulating layer 226 and the first upper insulating layer 236 may be formed of the same material, which may result in no interface therebetween. In this sense, the first lower insulating layer 226 and the first upper insulating layer 236 may constitute a single insulating layer. In another example, the first lower insulating layer 226 and the first upper insulating layer 236 may have a visible interface therebetween.

The rear side 230b of the first upper semiconductor chip 230 may be provided thereon with first structure pads 250. The first structure pads 250 may include metal, such as tin (Sn), lead (Pb), nickel (Ni), gold (Au), silver (Ag), copper (Cu), bismuth (Bi), or a combination thereof.

The first upper semiconductor chip 230 may be provided therein with first vias 240. The first vias 240 may extend from the rear side 230b toward the front side 230a of the first upper semiconductor chip 230. For example, the first vias 240 may penetrate the first upper semiconductor chip 230, and may have contact with the first structure pads 250 and the first upper chip pads 234. The first vias 240 may not penetrate the first lower semiconductor chip 220. The first vias 240 may have their lowermost ends at a higher level than that of the front side 220a of the first lower semiconductor chip 220. The first upper semiconductor chip 230 and the first lower semiconductor chip 220 may be electrically connected through the first vias 240 to the first structure pads 250.

In other embodiments, the first vias 240 may penetrate the first upper semiconductor chip 230 and have contact with the first upper conductive patterns 232. For example, the first lower semiconductor chip 220 may be connected to the first upper semiconductor chip 230 through the first lower chip pads 224 and the first upper chip pads 234, the first upper semiconductor chip 230 may be connected to the first structure pads 250 through the first upper conductive patterns 232 and the first vias 240.

The first adhesive layer 210 may be provided on the rear side 220b of the first lower semiconductor chip 220. The first adhesive layer 210 may include a die attach film (DAF). The first unit structure 200 may be attached through the first adhesive layer 210 to the top surface of the substrate 100.

The first unit structure 200 (the description thereof may also be applicable to the second unit structure 300 and the third unit structure 400) stacked in the semiconductor package 10 may have the semiconductor chips 220 and 230 that are in contact with each other to allow their front sides 220a and 230a to face in opposite directions. In example embodiments, “to face” means the active area (BEOL) of the two semiconductor chips 220, 230 face each other. Therefore, the first lower semiconductor chip 220 and the first upper semiconductor chip 230 may have different warpage directions in the first unit structure 200, and a force that tends to bend the first lower semiconductor chip 220 may counterbalance a force that tends to bend the first upper semiconductor chip 230. As a result, the semiconductor package 10 may have improved structural stability.

Furthermore, in the first unit structure 200, the first lower chip pads 224 and the first upper chip pads 234 may be in contact with each other, and accordingly the first lower semiconductor chip 220 and the first upper semiconductor chip 230 may be directly connected to each other. In this configuration, a short electrical path may be provided between the first lower semiconductor chip 220 and the first upper semiconductor chip 230, and thus the semiconductor package 10 may have improved electrical characteristics.

The second unit structure 300 may have substantially the same configuration as that of the first unit structure 200, and for convenience of description, the following will mainly explain a difference between the first and second unit structures 200 and 300.

The second unit structure 300 may include a second adhesive layer 310, a second lower semiconductor chip 320 on the second adhesive layer 310, a second upper semiconductor chip 330 on the second lower semiconductor chip 320, second structure pads 350 on a rear side 330b of the second upper semiconductor chip 330, and/or second vias 340 that penetrate the second upper semiconductor chip 330 and connect second upper chip pads 334 to the second structure pads 350.

A front side 320a of the second lower semiconductor chip 320 may be in contact with a front side 330a of the second upper semiconductor chip 330. For example, second lower chip pads 324 and a second lower insulating layer 326 may be in contact with the second upper chip pads 334 and a second upper insulating layer 336 respectively. The second lower insulating layer 326 and the second upper insulating layer 336 may be formed of the same material, which may result in no interface therebetween. In another example, the second lower insulating layer 326 and the second upper insulating layer 336 may have a visible interface therebetween.

The second adhesive layer 310 may be provided on a rear side 320b of the second lower semiconductor chip 320. The second unit structure 300 may be attached through the second adhesive layer 310 to the top surface of the first unit structure 200, whose top surface corresponds to the rear side 230b of the first upper semiconductor chip 230 and is hereinafter designated by the same reference numeral 230b. When viewed in plan, the second unit structure 300 may be shifted in the first direction D1 on the first unit structure 200. Therefore, the top surface 230b of the first unit structure 200 may be partially exposed, and one or more of the first structure pads 250 may also be exposed. The exposed one or more of the first structure pads 250 may be disposed on one side of the second unit structure 300.

The third unit structure 400 may have substantially the same configuration as that of the first unit structure 200, and for convenience of description, the following will mainly explain a difference the first and third unit structures 200 and 400.

The third unit structure 400 may include a third adhesive layer 410, a third lower semiconductor chip 420 on the third adhesive layer 410, a third upper semiconductor chip 430 on the third lower semiconductor chip 420, third structure pads 450 on a rear side 430b of the third upper semiconductor chip 430, and/or third vias 440 that penetrate the third upper semiconductor chip 430 and connect third upper chip pads 434 to the third structure pads 450.

A front side 420a of the third lower semiconductor chip 420 may be in contact with a front side 430a of the third upper semiconductor chip 430. For example, third lower chip pads 424 and a third lower insulating layer 426 may be in contact respectively with the third upper chip pads 434 and a third upper insulating layer 436. The third lower insulating layer 426 and the third upper insulating layer 436 may be formed of the same material, which may result in no interface therebetween. In another example, the third lower insulating layer 426 and the third upper insulating layer 436 may have a visible interface therebetween.

The third adhesive layer 410 may be provided on a rear side 420b of the third lower semiconductor chip 420. The third unit structure 400 may be attached through the third adhesive layer 410 to the top surface of the second unit structure 300, whose top surface corresponds to the rear side 330b of the second upper semiconductor chip 330 and is hereinafter designated by the same reference numeral 330b. When viewed in plan, the third unit structure 400 may be shifted in the first direction D1 on the second unit structure 300. In another example, when viewed in plan, the third unit structure 400 may be shifted in a direction opposite to the first direction D1 on the second unit structure 300. Therefore, the top surface 330b of the second unit structure 300 may be partially exposed, and one or more of the second structure pads 350 may also be exposed. The exposed one or more of the second structure pads 350 may be disposed on one side of the third unit structure 400.

The first, second, and third unit structures 200, 300, and 400 may be provided as discussed above.

In the unit structures 200, 300, and 400, the lower semiconductor chips 220, 320, and 420 may be in contact with corresponding upper semiconductor chips 230, 330, and 430, and one adhesive layer 210, 310, or 410 may be required to stack two chips (e.g., the lower and upper semiconductor chips of each of the unit structures 200, 300, and 400) on the substrate 100. In such cases, to stack the unit structures 200, 300, and 400, the needed number of the adhesive layers 210, 310, and 410 may be less than the number of the semiconductor chips 220, 230, 320, 330, 420, and 430, with the result that the semiconductor package 10 may decrease in thickness.

The unit structures 200, 300, and 400 may be connected to each other through the bonding wires 500, and may be wire-bonded to the substrate 100. For example, the bonding wires 500 may be coupled to the substrate pads 110 of the substrate 100, the first structure pads 250 of the first unit structure 200, the second structure pads 350 of the second unit structure 300, and the third structure pads 450 of the third unit structure 400. Because the unit structures 200, 300, and 400 constitute the offset stack structure, one or ones of the first, second, and third structure pads 250, 350, and 450 may be exposed. The bonding wires 500 may be coupled to the exposed first, second, and third structure pads 250, 350, and 450.

The first upper semiconductor chip 230 and the first lower semiconductor chip 220 may be connected to the substrate 100 through the first vias 240, the first structure pads 250, and the bonding wires 500. The second upper semiconductor chip 330 and the second lower semiconductor chip 320 may be connected to the substrate 100 through the second vias 340, the second structure pads 350, and the bonding wires 500. The third upper semiconductor chip 430 and the third lower semiconductor chip 420 may be connected to the substrate 100 through the third vias 440, the third structure pads 450, and the bonding wires 500.

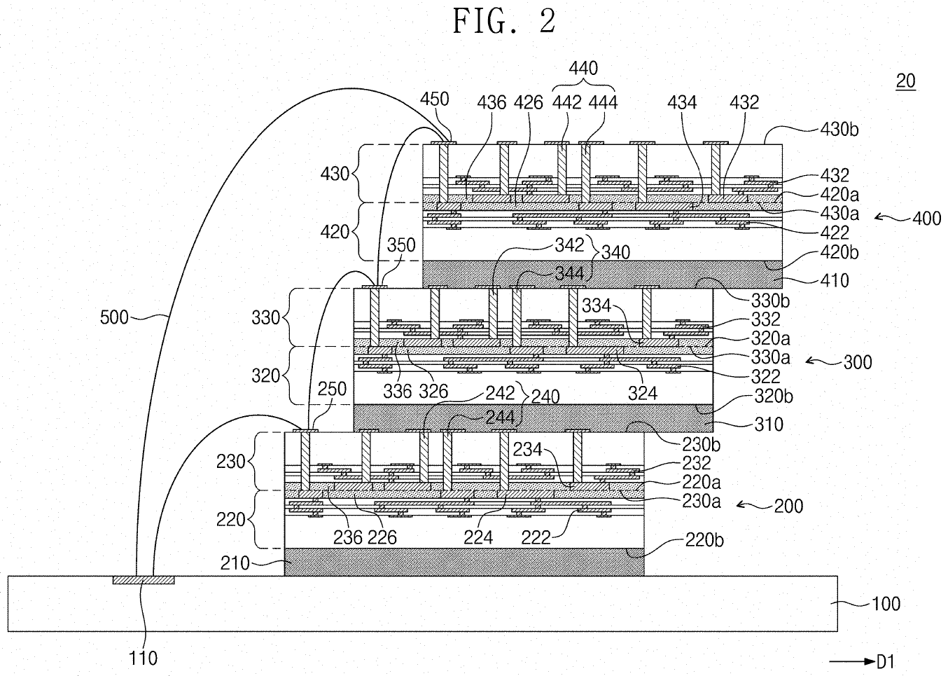

FIG. 2 illustrates a cross-sectional view showing a semiconductor package according to some example embodiments of the present inventive concepts. Hereinafter, components the same as those discussed above are allocated the same reference numerals thereto, and a repetitive explanation thereof will be omitted or abridged for convenience of description.

Referring to FIG. 2, a semiconductor package 20 may include the substrate 100 and the unit structures 200, 300, and/or 400.

The unit structures 200, 300, and/or 400 may be provided on the substrate 100. The unit structures 200, 300, and/or 400 may be disposed to constitute an offset stack structure and may be connected to each other through the bonding wires 500. Although the following description is directed toward the first unit structure 200, this description is also applicable to the second and third unit structures 300 and 400.

The front side 220a of the first lower semiconductor chip 220 may be in contact with the front side 230a of the first upper semiconductor chip 230. The first lower insulating layer 226 may be in contact with the first upper insulating layer 236.

The first lower chip pads 224 may not be in contact with the first upper chip pads 234. For example, when viewed in plan, the first lower chip pads 224 may be spaced apart from the first upper chip pads 234.

The first vias 240 may be provided in the first upper semiconductor chip 230. The first vias 240 may extend from the rear side 230b toward the front side 230a of the first upper semiconductor chip 230. The first vias 240 may include first upper vias 242 and first lower vias 244. For example, the first upper vias 242 may penetrate the first upper semiconductor chip 230, and may contact the first structure pads 250 and the first upper chip pads 234. For example, the first lower vias 244 may penetrate the first upper semiconductor chip 230 and the first upper insulating layer 236, and may contact the first structure pads 250 and the first lower chip pads 224. The first lower vias 244 may not be in contact with the first upper chip pads 234. When viewed in plan, the first lower vias 244 may be spaced apart from the first upper chip pads 234. The first upper semiconductor chip 230 may be electrically connected through the first upper vias 242 to the first structure pads 250, and the first lower semiconductor chip 220 may be electrically connected through the first lower vias 244 to the first structure pads 250.

In other embodiments, the first upper vias 242 may penetrate the first upper semiconductor chip 230 and contact the first upper conductive patterns 232, and the first lower vias 244 may penetrate the first upper semiconductor chip 230, the first upper insulating layer 236, and the first lower insulating layer 226 and contact the first lower conductive patterns 222. In this configuration, the first upper semiconductor chip 230 may be connected to the first structure pads 250 through the first upper conductive patterns 232 and the first upper vias 242, and the first lower semiconductor chip 220 may be connected to the first structure pads 250 through the first lower conductive patterns 222 and the first lower vias 244.

The second and third unit structures 300 and 400 may have substantially the same configuration as that of the first unit structure 200.

For convenience of description, the explanation has been made for each of FIGS. 1 and 2, but the embodiments of respective drawings may be incorporated to achieve a new embodiment. In addition, a semiconductor package may be neither limited nor applicable to the configuration and method discussed above, but all or some of the embodiments may be selectively combined and then configured in various ways.

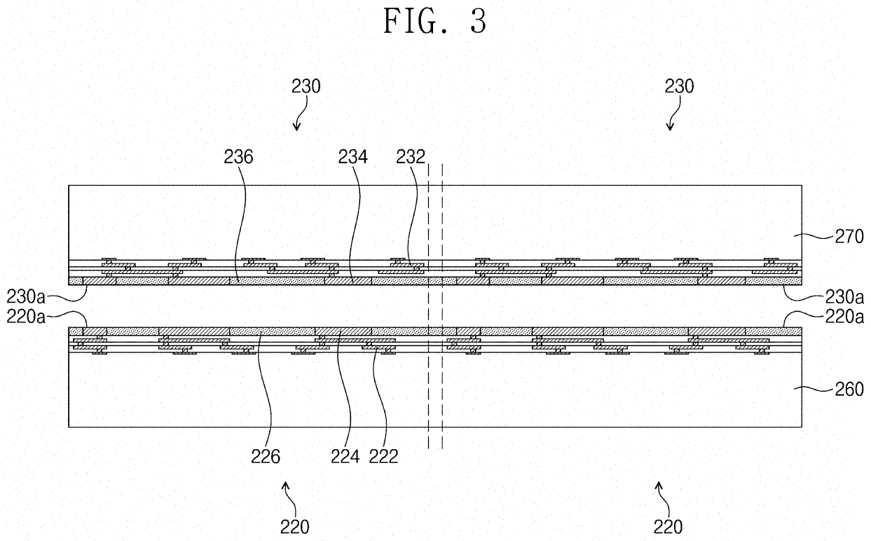

FIGS. 3 to 10 illustrate cross-sectional views showing a method of manufacturing a semiconductor package according to some example embodiments of the present inventive concepts.

Referring to FIG. 3, a first semiconductor substrate 260 may be provided. The first semiconductor substrate 260 may be a wafer-level substrate made of a semiconductor material, such as silicon.

A plurality of first lower semiconductor chips 220 may be fabricated on a top surface of the first semiconductor substrate 260. The first lower semiconductor chips 220 may be fabricated by forming integrated circuits on the top surface of the first semiconductor substrate 260. First lower conductive patterns 222 and first lower chip pads 224 may be formed on a front side 220a of each of the first lower semiconductor chips 220, which patterns 222 and pads 224 are connected to the integrated circuits. The first lower conductive patterns 222 may be covered with a first lower insulating layer 226. The first lower chip pads 224 may have their top surfaces coplanar with that of the first lower insulating layer 226. For example, the front side 220a of the first lower semiconductor chip 220 may be substantially flat. The first lower insulating layer 226 may include oxide, such as silicon oxide (SiOx).

A second semiconductor substrate 270 may be provided. The second semiconductor substrate 270 may be a wafer-level substrate made of a semiconductor material, such as silicon.

A plurality of first upper semiconductor chips 230 may be fabricated on a top surface of the second semiconductor substrate 270. The first upper semiconductor chips 230 may be fabricated by forming integrated circuits on the top surface of the second semiconductor substrate 270. First upper conductive patterns 232 and first upper chip pads 234 may be formed on a front side 230a of each of the first upper semiconductor chips 230, which patterns 232 and pads 234 are connected to the integrated circuits. The first upper conductive patterns 232 may be covered with a first upper insulating layer 236. The first upper chip pads 234 may have their top surfaces coplanar with that of the first upper insulating layer 236. For example, the front side 230a of the first upper semiconductor chip 230 may be substantially flat. The first upper insulating layer 236 may include the same material as that of the first lower insulating layer 226. The first upper insulating layer 236 may include oxide, such as silicon oxide.

The second semiconductor substrate 270 may be placed above the first semiconductor substrate 260. The second semiconductor substrate 270 may be disposed to allow the front sides 230a of the first upper semiconductor chips 230 to face the front sides 220a of the first lower semiconductor chips 220. In example embodiments, “to face” means the active area (BEOL) of the first upper semiconductor chips 230 and first lower semiconductor chips 220 face each other. In example embodiments, the first upper semiconductor chips 230 may be aligned with the first lower semiconductor chips 220. For example, when viewed in plan, the first upper chip pads 234 of the first upper semiconductor chips 230 may be aligned with the first lower chip pads 224 of the first lower semiconductor chips 220.

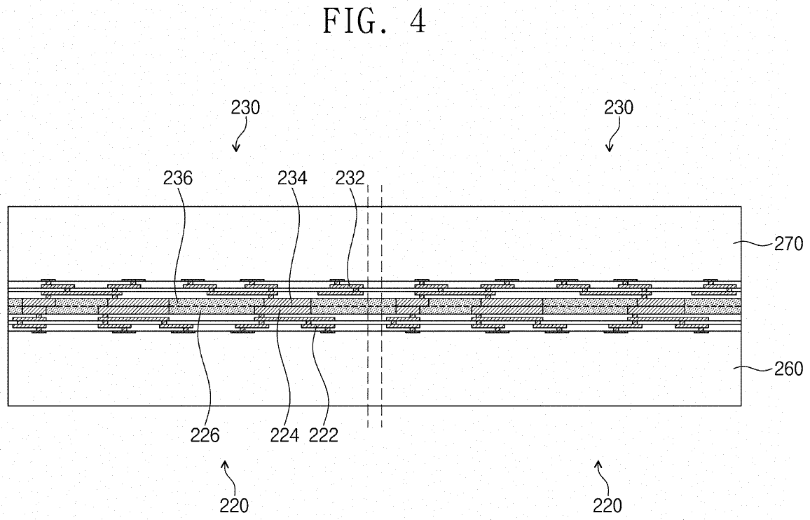

Referring to FIG. 4, the second semiconductor substrate 270 may contact the first semiconductor substrate 260. For example, the first upper chip pads 234 of the first upper semiconductor chips 230 may contact the first lower chip pads 224 of the first lower semiconductor chips 220. The first upper insulating layer 236 may contact the first lower insulating layer 226.

The first upper insulating layer 236 may be combined with the first lower insulating layer 226. For example, the first upper insulating layer 236 and the first lower insulating layer 226 may be combined with each other to form a single insulating layer. The combination of the first upper insulating layer 236 and the first lower insulating layer 226 may be automatically performed. For example, the first upper insulating layer 236 and the first lower insulating layer 226 may be formed of the same material (e.g., silicon oxide), and then may be combined with each other due to an oxide-to-oxide bonding caused by surface activation at an interface between the first upper insulating layer 236 and the first lower insulating layer 226 that are in contact with each other. The combination of the first upper insulating layer 236 and the first lower insulating layer 226 may vanish the interface therebetween. In another example, the interface between the first lower insulating layer 226 and the first upper insulating layer 236 may appear in sight.

Before the first semiconductor substrate 260 and the second semiconductor substrate 270 are in contact with each other, for the purpose of easy combination, a pre-treatment process may be performed on the first semiconductor substrate 260 and the second semiconductor substrate 270. For example, the pre-treatment process may include a cleaning process to clean surfaces of the first upper and lower insulating layers 236 and 226 or a grinding process to flat grind surfaces of the first upper and lower insulating layers 236 and 226. An annealing process may further be performed on the first and second semiconductor substrates 260 and 270 to accelerate the combination of the first upper and lower insulating layers 236 and 226. In another example, the combination of the first upper and lower insulating layers 236 and 226 may be accelerated due to heat or pressure provided in a subsequent process.

As shown in FIG. 4, when the first lower chip pads 224 are in contact with the first upper chip pads 234, the first lower chip pads 224 and their corresponding first upper chip pads 234 may be combined with each other. For example, the first lower chip pads 224 and the first upper chip pads 234 may be combined by a metal-to-metal thermal compression bonding method or other metal-to-metal bonding methods. In other embodiments, the first lower chip pads 224 and the first upper chip pads 234 may not be combined with each other, but may remain as individual components.

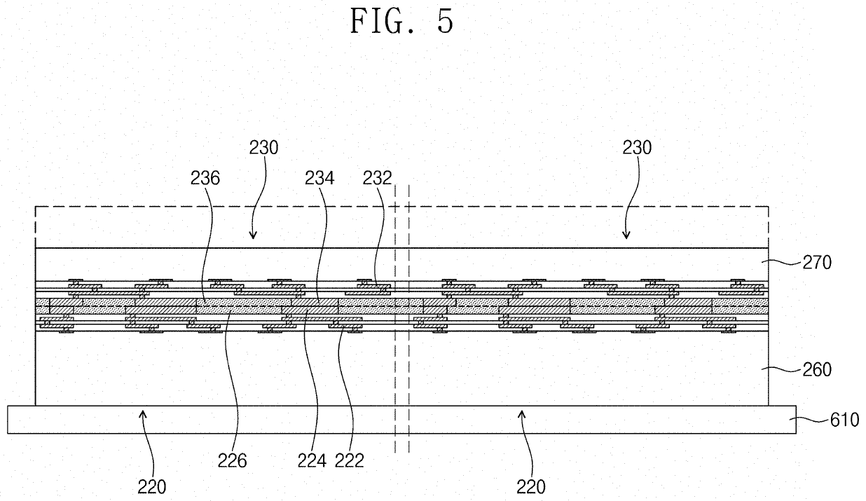

Referring to FIG. 5, the second semiconductor substrate 270 may be partially removed. In detail, the second semiconductor substrate 270 may become reduced in thickness. For example, a first carrier substrate 610 may be provided on the first semiconductor substrate 260. The first semiconductor substrate 260 may be attached through an adhesive to the first carrier substrate 610. After that, a grinding process may be performed on one side of the second semiconductor substrate 270.

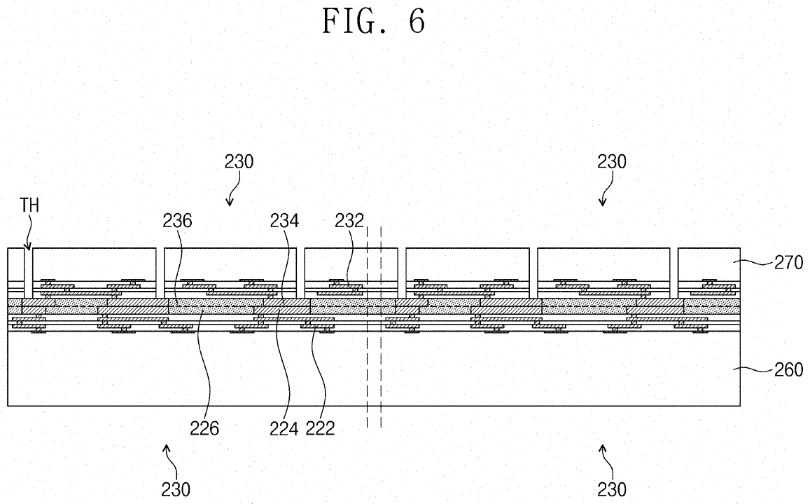

Referring to FIG. 6, the first carrier substrate 610 may be removed, and then through holes TH may be formed in the second semiconductor substrate 270. The through holes TH may penetrate the second semiconductor substrate 270, exposing the first upper chip pads 234 of the first upper semiconductor chips 230. The through holes TH may define areas where first vias 240 are formed in a subsequent process.

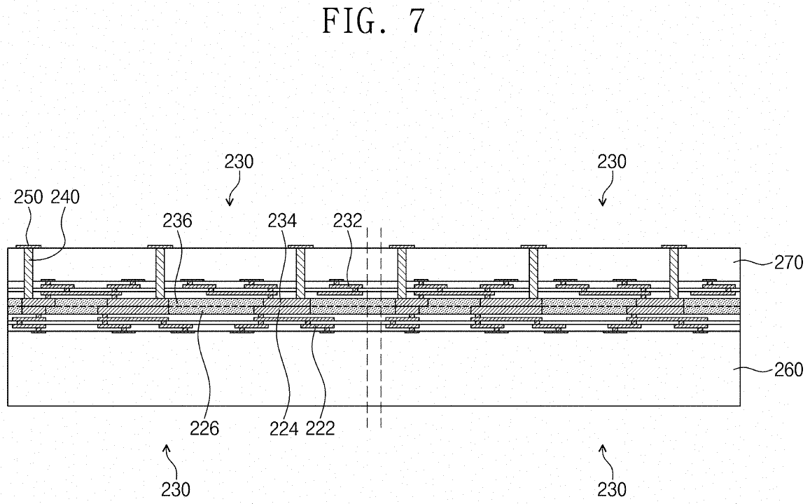

Referring to FIG. 7, first vias 240 may be formed. The first vias 240 may be formed by filling the though holes TH with a conductive material. For example, the second semiconductor substrate 270 may be deposited or plated thereon with a conductive material to fill the through holes TH and to cover a top surface of the second semiconductor substrate 270, and then the conductive material may be removed from the top surface of the second semiconductor substrate 270.

First structure pads 250 may be formed on the top surface of the second semiconductor substrate 270. For example, the first structure pads 250 may be formed by depositing a conductive material on the second semiconductor substrate 270 and patterning the conductive material. The first structure pads 250 may be formed to have connection with the first vias 240.

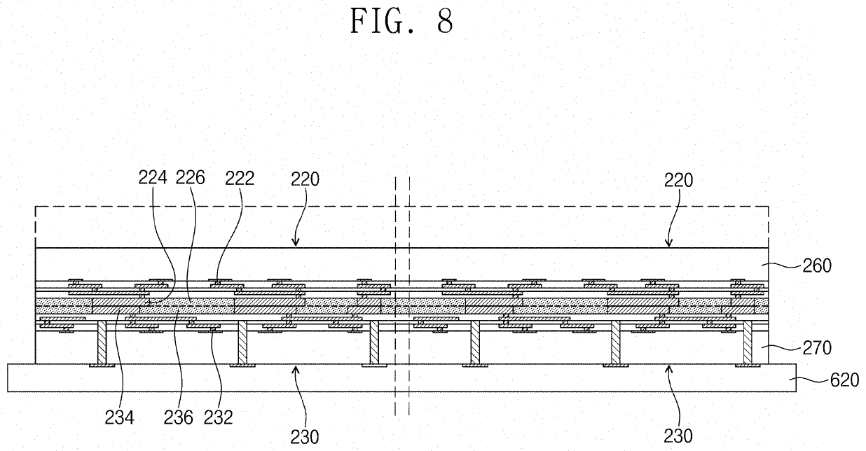

Referring to FIG. 8, the first semiconductor substrate 260 may be partially removed. In detail, the first semiconductor substrate 260 may become reduced in thickness. For example, a second carrier substrate 620 may be provided on the second semiconductor substrate 270. The second semiconductor substrate 270 may be attached through an adhesive to the second carrier substrate 620. After that, a grinding process may be performed on one side of the first semiconductor substrate 260.

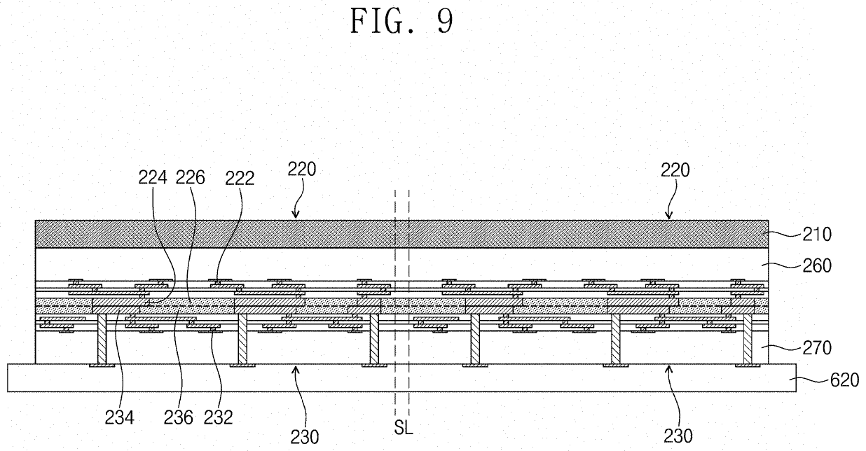

Referring to FIG. 9, a first adhesive layer 210 may be formed on the first semiconductor substrate 260. For example, the first adhesive layer 210 may be formed by attaching a die attach film (DAF) on the one side of the first semiconductor substrate 260.

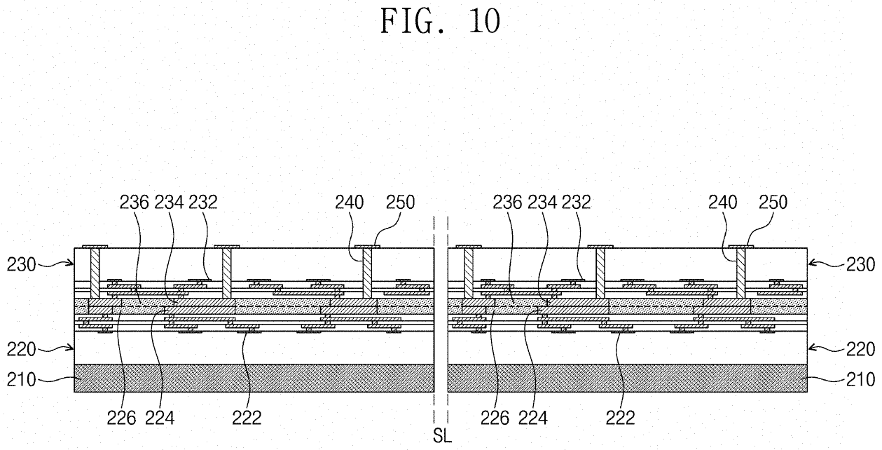

Referring to FIG. 10, the second carrier substrate 620 may be removed, and then the first and second semiconductor substrates 260 and 270 may be cut into first upper semiconductor chips 230 separated from each other and into first lower semiconductor chips 220 separated from each other. For example, the first semiconductor substrate 260, the second semiconductor substrate 270, and the first adhesive layer 210 may undergo a singulation process performed along a sawing line SL. Thus, the first semiconductor substrate 260, the second semiconductor substrate 270, and the first adhesive layer 210 may be diced into a plurality of first unit structures 200 separated from each other. Each of the first unit structures 200 may be substantially the same as the first unit structure 200 of FIG. 1.

Although not shown, the formation of a second unit structure 300 and a third unit structure 400 of FIG. 1 may be substantially identical to that of the first unit structure 200. In another example, the second and third unit structures 300 and 400 may be formed together with the first unit structure 200, and then the singulation process discussed with reference to FIG. 10 may be performed to separate the first, second, and third unit structures 200, 300, and 400 from each other. For convenience, the following description will omit the formation of the second and third unit structures 300 and 400.

Referring back to FIG. 1, the first unit structure 200, the second unit structure 300, and the third unit structure 400 may be stacked on a substrate 100. For example, the first unit structure 200 may be attached to the substrate 100. The first adhesive layer 210 may be used to attach the first unit structure 200 to the substrate 100. The second unit structure 300 may be attached to the first unit structure 200. A second adhesive layer 310 may be used to attach the second unit structure 300 to a top surface of the first unit structure 200. When viewed in plan, the second unit structure 300 may be shifted on the first unit structure 200. The shift of the second unit structure 300 may expose one or more of the first structure pads 250 of the first unit structure 200. The third unit structure 400 may be attached to the second unit structure 300. A third adhesive layer 410 may be used to attach the third unit structure 400 to a top surface of the second unit structure 300. When viewed in plan, the third unit structure 400 may be shifted on the second unit structure 300. The shift of the third unit structure 400 may expose one or more of second structure pads 350 of the second unit structure 300.

The first, second, and third unit structures 200, 300, and 400 may be wire-bonded to the substrate 100. For example, bonding wires 500 may be used to electrically connect substrate pads 110 of the substrate 100, the first structure pads 250 of the first unit structure 200, the second structure pads 350 of the second unit structure 300, and the third structure pad 450 of the third unit structure 400. Through the aforementioned processes, a semiconductor package 10 of FIG. 1 may be fabricated.

In the fabrication of the semiconductor package 10, the unit structures 200, 300, and/or 400 may be mounted in such a way that the bonding wires 500 are connected to the unit structures 200, 300, and/or 400 instead of to semiconductor chips. Therefore, the number of wire bonding processes may be less the number of semiconductor chips. As a result, the fabrication of the semiconductor package 10 may be simplified.

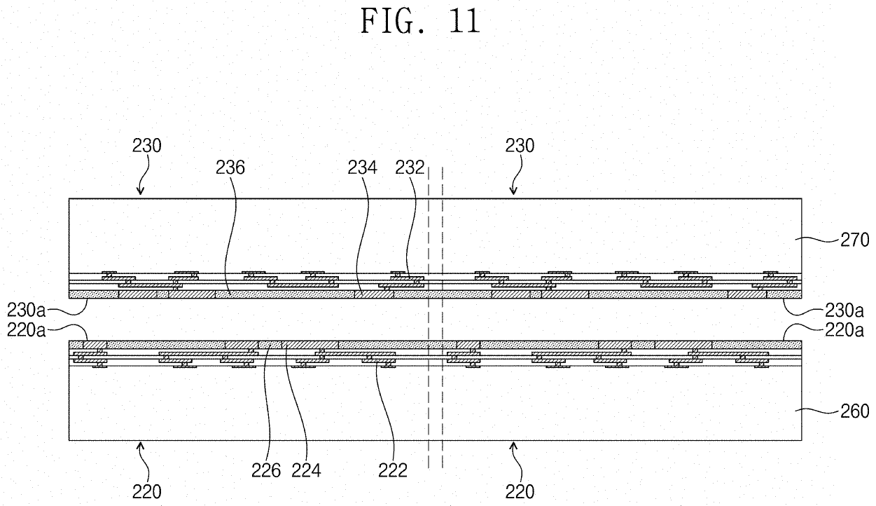

FIGS. 11 to 14 illustrate cross-sectional views showing a method of manufacturing a semiconductor package according to some example embodiments of the present inventive concepts.

Referring to FIG. 11, the first semiconductor substrate 260 and the second semiconductor substrate 270 may be provided.

A plurality of the first lower semiconductor chips 220 may be fabricated on the first semiconductor substrate 260. The first lower semiconductor chips 220 may be fabricated by forming integrated circuits on the top surface of the first semiconductor substrate 260. The first lower conductive patterns 222 and the first lower chip pads 224 may be formed on the front side 220a of the first lower semiconductor chips 220, which patterns 222 and pads 224 are connected to the integrated circuits.

A plurality of the first upper semiconductor chips 230 may be fabricated on the second semiconductor substrate 270. The first upper semiconductor chips 230 may be fabricated by forming integrated circuits on the top surface of the second semiconductor substrate 270. The first upper conductive patterns 232 and the first upper chip pads 234 may be formed on the front side 230a of the first upper semiconductor chips 230, which patterns 232 and pads 234 are connected to the integrated circuits.

The second semiconductor substrate 270 may be placed above the first semiconductor substrate 260. The second semiconductor substrate 270 may be disposed to allow the front sides 230a of the first upper semiconductor chips 230 to face the front sides 220a of the first lower semiconductor chips 220. In example embodiments, “to face” means the active area (BEOL) of the first upper semiconductor chips 230 and first lower semiconductor chips 220 face each other. When viewed in plan, the first upper chip pads 234 of the first upper semiconductor chips 230 may be spaced apart from the first lower chip pads 224 of the first lower semiconductor chips 220.

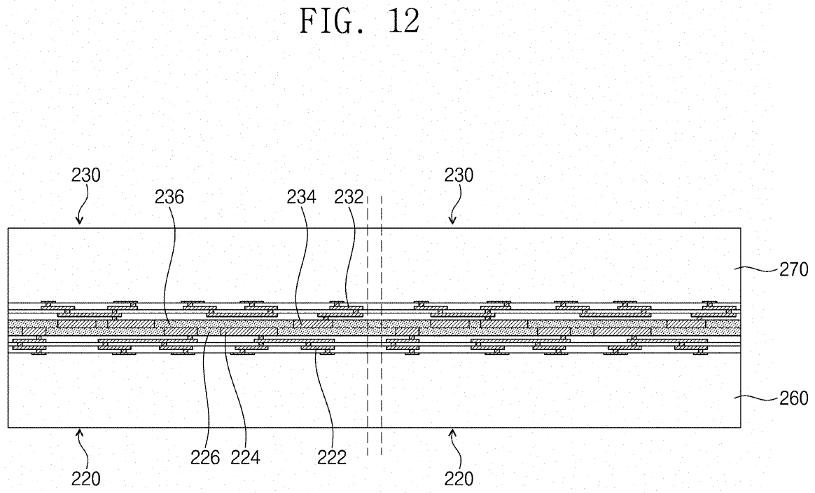

Referring to FIG. 12, the second semiconductor substrate 270 may contact the first semiconductor substrate 260. For example, the first upper insulating layer 236 may contact the first lower insulating layer 226. The first upper insulating layer 236 may be combined with the first lower insulating layer 226. For example, the first upper insulating layer 236 and the first lower insulating layer 226 may be combined with each other to form a single insulating layer.

The first upper chip pads 234 of the first upper semiconductor chips 230 may not contact the first lower chip pads 224 of the first lower semiconductor chips 220.

The process discussed with reference to FIG. 5 may be performed on a resultant structure of FIG. 12. For example, the second semiconductor substrate 270 may become reduced in thickness.

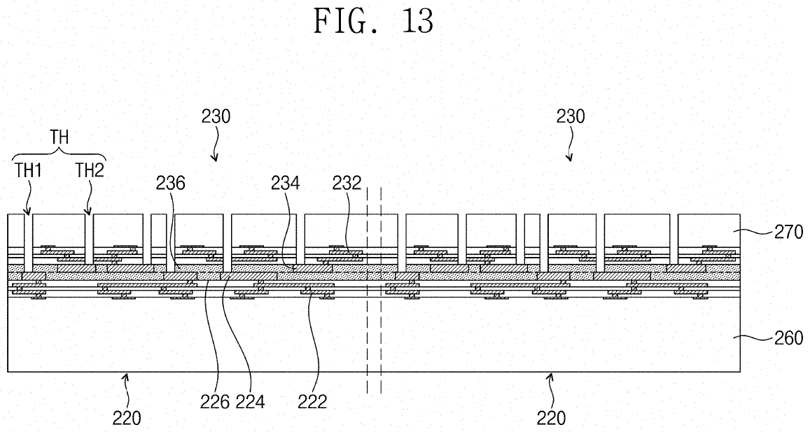

Referring to FIG. 13, the through holes TH may be formed in the second semiconductor substrate 270. The through holes TH may include first through holes TH1 and second through holes TH2. The first through holes TH1 may penetrate the second semiconductor substrate 270, exposing the first upper chip pads 234 of the first upper semiconductor chips 230. The second through holes TH2 may penetrate the second semiconductor substrate 270 and the first upper insulating layer 236, exposing the first lower chip pads 224 of the first lower semiconductor chips 220. The second through holes TH2 may not contact the first upper chip pads 234. The first through holes TH1 may define areas where first upper vias 242 are formed in a subsequent process. The second through holes TH2 may define areas where first lower vias 244 are formed in a subsequent process.

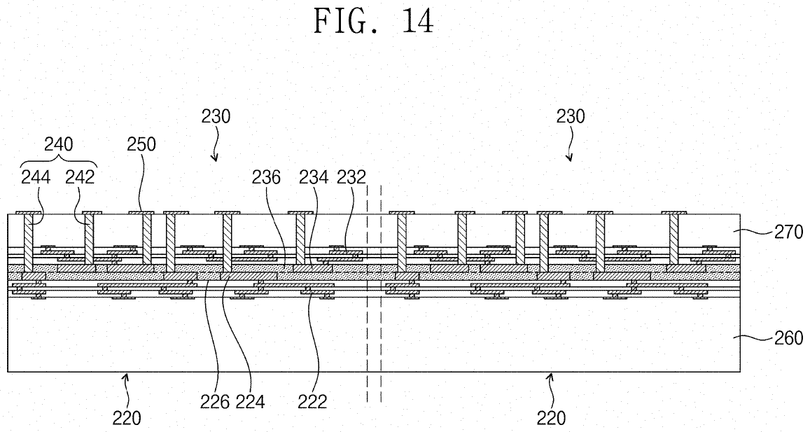

Referring to FIG. 14, the first vias 240 may be formed. The first vias 240 may include first upper vias 242 formed in the first through holes TH1 and first lower vias 244 formed in the second through holes TH2. The first vias 240 may be formed by filling the first through holes TH1 and the second through holes TH2 with a conductive material. For example, the formation of the first upper vias 242 and the first lower vias 244 may include depositing or plating a conductive material on the second semiconductor substrate 270, and then removing the conductive material from the top surface of the second semiconductor substrate 270.

The first structure pads 250 may be formed on the top surface of the second semiconductor substrate 270. For example, the first structure pads 250 may be formed by depositing a conductive material on the second semiconductor substrate 270 and patterning the conductive material. The first structure pads 250 may be formed to have connection with the first upper vias 242 and the first lower vias 244.

The processes discussed with reference to FIGS. 8, 9, and 10 may be performed on a resultant structure of FIG. 14. For example, the first semiconductor substrate 260 may be partially removed. The first adhesive layer 210 may be formed on the first semiconductor substrate 260. The first semiconductor substrate 260, the second semiconductor substrate 270, and the first adhesive layer 210 may be diced into a plurality of the first unit structures 200 separated from each other. The second and third unit structures 300 and 400 may be formed by substantially the same process as that of the first unit structure 200, or may be formed together with the first unit structure 200.

Referring back to FIG. 2, the first unit structure 200, the second unit structure 300, and/or the third unit structure 400 may be stacked on the substrate 100. The first adhesive layer 210 may be used to attach the first unit structure 200 to the substrate 100. The second unit structure 300 may be attached to the first unit structure 200. The third unit structure 400 may be attached to the second unit structure 300. The first, second, and third unit structures 200, 300, and 400 may be stacked to constitute an offset stack structure. Therefore, one or more of the first structure pads 250 of the first unit structure 200 may be exposed, and one or more of the second structure pads 350 of the second unit structure 300 may be exposed.

The first, second, and third unit structures 200, 300, and/or 400 may be wire-bonded to the substrate 100. Through the aforementioned processes, a semiconductor package 20 of FIG. 2 may be fabricated.

According to some example embodiments of the present inventive concepts, a semiconductor package may be configured such that a force that tends to bend a lower semiconductor chip counterbalances a force that tends to bend an upper semiconductor chip. As a result, the semiconductor package may improve in structural stability.

In addition, the semiconductor package may be configured such that the lower and upper semiconductor chips of unit structures are combined with each other, and that the needed number of adhesive layers is less than the number of the semiconductor chips, which may result in a reduction in thickness of the semiconductor package.

Furthermore, the unit structures may have short electrical paths between the lower and upper semiconductor chips, and thus the semiconductor package may improve in electrical characteristics.

In a method of manufacturing a semiconductor package according to some example embodiments of the present inventive concepts, when the unit structures are mounted, the number of wire bonding processes may be less than the number of the semiconductor chips. As a result, the fabrication of the semiconductor package may be simplified.

Although the present invention has been described in connection with some example embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A semiconductor package, comprising:
a substrate;
a first unit structure attached to the substrate; and
a second unit structure attached to the first unit structure,
wherein each of the first and second unit structures comprises:
an adhesive layer;
a lower semiconductor chip on the adhesive layer;
an upper semiconductor chip on and in contact with the lower semiconductor chip; and
a plurality of vias penetrating the upper semiconductor chip and connecting with the lower and upper semiconductor chips.

2. The semiconductor package of claim 1, wherein
the lower semiconductor chip comprises:
a lower chip pad on a front side of the lower semiconductor chip; and
a lower insulating layer surrounding the lower chip pad on the front side of the lower semiconductor chip, and
the upper semiconductor chip comprises:
an upper chip pad on a front side of the upper semiconductor chip; and
an upper insulating layer surrounding the upper chip pad on the front side of the upper semiconductor chip.

3. The semiconductor package of claim 2, wherein the lower semiconductor chip and the upper semiconductor chip are arranged to allow the front side of the lower semiconductor chip to face the front side of the upper semiconductor chip,
wherein the lower insulating layer of the lower semiconductor chip and the upper insulating layer of the upper semiconductor chip are in contact with each other.

4. The semiconductor package of claim 2, wherein the lower insulating layer of the lower semiconductor chip and the upper insulating layer of the upper semiconductor chip constitute a single body of the same material.

5. The semiconductor package of claim 2, wherein the lower chip pad of the lower semiconductor chip and the upper chip pad of the upper semiconductor chip are in contact with each other,
wherein the plurality of vias penetrate the upper semiconductor chip and contact the upper chip pad.

6. The semiconductor package of claim 2, wherein, when viewed in plan, the lower chip pad of the lower semiconductor chip and the upper chip pad of the upper semiconductor chip are spaced apart from each other, wherein
one of the plurality of vias penetrates the upper semiconductor chip and contacts the upper chip pad, and
another one of the plurality of vias penetrates the upper semiconductor chip and contacts the lower chip pad.

7. The semiconductor package of claim 6, wherein, when viewed in plan, the another one of the plurality of vias that contacts the lower chip pad is spaced apart from the upper chip pad.

8. The semiconductor package of claim 1, wherein the first unit structure and the second unit structure constitute an offset stack structure having a staircase shape that ascends in a direction parallel to a top surface of the substrate.

9. The semiconductor package of claim 1, wherein each of the first and second unit structures further comprises a structure pad on a rear side of the upper semiconductor chip, the structure pad being coupled through the plurality of vias to the upper and lower semiconductor chips,
wherein the structure pad is wire-bonded to the substrate.

10. The semiconductor package of claim 9, wherein the structure pad of the first unit structure is on a top surface of the first unit structure, the top surface being on one side of the second unit structure and exposed by the second unit structure.

11. The semiconductor package of claim 1, wherein lowermost ends of the vias are at a higher level than that of a front side of the lower semiconductor chip.

12. A method of manufacturing a semiconductor package, the method comprising:
forming a unit structure;
attaching the unit structure to a substrate; and
connecting the unit structure to the substrate via a bonding wire,
wherein forming the unit structure comprises:
providing a lower semiconductor chip having on a front side thereof a lower chip pad and a lower insulating layer;
providing an upper semiconductor chip having on a front side thereof an upper chip pad and an upper insulating layer;
disposing the upper semiconductor chip on the lower semiconductor chip such that the upper insulating layer and the lower insulating layer are in contact with each other;
forming vias that penetrate the upper semiconductor chip;
forming a structure pad on a rear side of the upper semiconductor chip; and
forming an adhesive layer on a rear side of the lower semiconductor chip.

13. The method of claim 12, wherein the vias connect the lower chip pad and the upper chip pad to the structure pad.

14. The method of claim 13, wherein the lower chip pad and the upper chip pad are in contact with each other,
wherein the vias are formed to penetrate the upper semiconductor chip and to have contact with the upper chip pad.

15. The method of claim 12, wherein, after the upper semiconductor chip is on the lower semiconductor chip,
the lower insulating layer and the upper insulating layer are combined with each other to form an insulating layer.

16. The method of claim 12, further comprising one or both of the following:
before forming the vias, performing a first thinning process on the rear side of the upper semiconductor chip; and
before forming the adhesive layer, performing a second thinning process on the rear side of the lower semiconductor chip.

17. The method of claim 12, wherein the adhesive layer is used to attach the unit structure to the substrate.

18. The method of claim 12, wherein forming the unit structure includes forming a plurality of unit structures, and
the method further comprises, stacking the plurality of unit structures before connecting the unit structures to the substrate.

19. The method of claim 18, wherein the adhesive layer of one of the unit structures is attached to the upper semiconductor chip included in another one of the unit structures.

20. The method of claim 18, wherein stacking the unit structures comprises offset-stacking the unit structures to shift in a direction parallel to a top surface of the substrate, in a plan view.
